(19) United States
(12) Patent Application Publication
(10) Pub. No.: US 2012/0151293 A1
(43) Pub. Date: Jun. 14, 2012

(54) Sequenced Two-Dimensional Codes in Video

(75) Inventor: William Michael Beals, Englewood, CO (US)

(73) Assignee: EchoStar Technologies L.L.C., Englewood, CO (US)

(21) Appl. No.: 12/964,478

(22) Filed: Dec. 9, 2010

(51) Int. Cl. G06F 11/08; H03M 13/00

(52) U.S. Cl. 714/755; 714/E11.03

(57) ABSTRACT

One embodiment described herein may take the form of a system or method for generating and/or receiving a plurality of sequenced matrix codes, such as QR codes, containing information such that the matrix codes may be decoded and analyzed in sequence to retrieve the stored information. In one embodiment, sequencing information may be embedded in one or more of the plurality of sequenced matrix codes to aid in receiving and decoding the codes in the proper and intended order. This sequencing information may be retrieved and maintained by a reader device to ensure that each matrix code in the sequence is received. Further, the plurality of sequenced matrix codes may be provided through a series of images, such as a video component of a multimedia presentation that may be received by the reader device.

### TECHNICAL FIELD

Embodiments disclosed herein relate generally to providing information two-dimensional codes, and more particularly to generating a sequence of two-dimensional codes in a video format to provide segmented information to a reader device.

### BACKGROUND

Barcodes and other optical machine-readable data representations are often used in commerce to provide a quick method of obtaining information about a product or service. In general, a barcode consists of varying widths of lines that may be read by a scanner, where the widths and spaces between the lines of the barcode provide information, such as an identification number of a product. Because the information of a barcode is conveyed through the varying widths of the lines of the code, barcodes are often referred to as linear or one-dimensional (1D) codes. In more recent years, a matrix (or two-dimensional) code has been developed to provide additional information in the code by encoding information in both the width and height dimensions of the matrix. Matrix codes, one example of which is as a quick response (QR) code, generally consist of black modules arranged in a square pattern on a white background, the configuration of which provides information to a scanner or reader. In general, while capable of containing more information that a typical barcode, the information storage capacity of matrix codes is still typically limited. For example, QR codes are typically limited to around 7,000 numeric characters or a few thousand alphanumeric characters.

### BRIEF SUMMARY

One implementation may take the form of a method for transmitting information in a plurality of matrix codes. The method may include the operations of deriving, utilizing an electronic device, information to be transmitted in the plurality of matrix codes and segmenting, utilizing an electronic device, the information into a plurality of segments corresponding to the plurality of matrix codes. In addition, the method may further include the operations of generating, utilizing an electronic device, the plurality of matrix codes wherein the plurality of matrix codes include the segmented information and at least one of the plurality of matrix codes includes sequence information corresponding to the plurality of matrix codes and transmitting, utilizing the electronic device, the plurality of matrix codes to at least one display device in a video component of a multimedia presentation. Further, the plurality of matrix codes is decodable by at least one reader device that optically detects the plurality of matrix codes displayed on the at least one display device to obtain the information included in the plurality of matrix codes.

Another embodiment may take the form of a method for receiving information encoded in a sequence of a plurality of matrix codes. The method may include the operations of receiving a first matrix code of the sequence of the plurality of matrix codes, the first matrix code including a first segment of information and a first set of sequence information corresponding to the plurality of matrix codes and decoding the first matrix code to obtain the first segment of information and the first set of sequence information. In addition, the method may include the operations of receiving at least a second matrix code of the sequence of the plurality of matrix codes, the second matrix code including a second segment of information, decoding the second matrix code to obtain the second segment of information and determining if the second matrix code is the last matrix code in the sequence of the plurality of matrix codes. Finally, the method may include the operation of combining the first segment of information and the second segment of information if the second matrix code is the last matrix code in the sequence of the plurality of matrix codes.

Yet another embodiment may take the form of a reader device comprising at least one processing unit and a storage medium, the storage medium storing a computer-executable code that, when executed by the at least one processing unit, causes the reader device to perform the certain operations. These operations may include a first operation of utilizing an optical component to obtain a first video image of a display device, the first video image including a first matrix code of a sequence of a plurality of matrix codes, the first matrix code including an encoded first segment of information and a first set of sequence information corresponding to the plurality of matrix codes. In addition, the reader device may include operations of decoding the first matrix code to obtain the first segment of information and the first set of sequence information, maintaining an image of the first matrix code, utilizing the optical component to obtain a second video image of a display device, the second video image including a matrix code and comparing the first video image and the second video image to determine the presence of a new matrix code in the second video image. Further, the operations may include decoding the new matrix code to obtain a second segment of information if a new matrix code is included in the second video image and combining the first segment of information and the second segment of information

### BRIEF DESCRIPTION OF THE DRAWINGS

FIG. 1 is a block diagram illustrating a system for facilitating generation of a plurality of sequenced matrix codes to provide encoded information beyond that of a single matrix code.

FIG. 2 is a flowchart depicting a method for an electronic device for generating a plurality of sequenced matrix codes for display in sequence to provide encoded information beyond that of a single matrix code.

FIG. 3 is an exemplary system for providing and receiving a plurality of sequenced matrix codes.

FIG. 4 is a flowchart depicting a first exemplary method for an electronic device for receiving and decoding a plurality of sequenced matrix codes in sequence to receive information contained within the matrix codes.

FIG. 5 is a flowchart depicting a second exemplary method for an electronic device for receiving and decoding a plurality of sequenced matrix codes in sequence to receive information contained within the matrix codes.

### DETAILED DESCRIPTION

One embodiment described herein may take the form of a system or method for generating and/or receiving a plurality of sequenced matrix codes, such as QR codes, containing encoded information such that the sequence of matrix codes may be decoded and analyzed to retrieve the stored information. In one embodiment, sequencing information may be embedded in one or more of the plurality of sequenced matrix codes to aid in receiving and decoding the codes in the proper and intended order. For example, the first generated matrix code may include an indicator within the matrix identifying that particular matrix code as the first of a sequence. In addition, the matrix code may include information setting forth the total number of matrix codes included in the sequence of codes. This sequencing information may be retrieved and processed by a reader device to ensure that each matrix code in the sequence is received. In another embodiment, the matrix codes and/or the information contained within the matrix codes (including the sequencing information) may be forwarded to a recipient device for processing. Further, the plurality of sequenced matrix codes may be provided through a series of images on a display device, such as a video component of a multimedia presentation that may be received by the reader device.

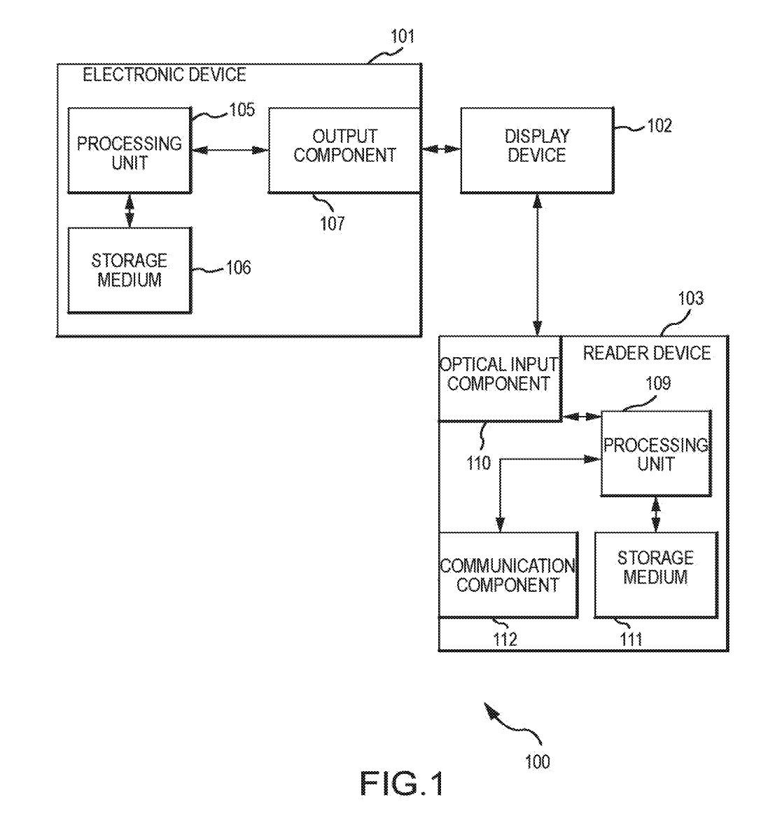

FIG. 1 is a block diagram illustrating a system 100 for facilitating generation of a plurality of sequenced matrix codes that may provide encoded information beyond that of a single matrix code. The system 100 may include a electronic device 101 (which may be any kind of electronic device such as a television, a television receiver, a digital video recorder, a digital video disc player, an automobile, a computing device, a telephone, a kitchen appliance, a video game system, a security system, and so on), at least one display device 102 (which may be any kind of display device such as a cathode ray tube display, a liquid crystal display, a television, a computer monitor, and so on), and a reader device 103 (which may be any kind of device capable of detecting and decoding a matrix code such as a telephone equipped with a camera, a mobile computing device that includes a camera, and so on).

The electronic device 101 may include one or more processing units 105, one or more non-transitory storage media 106 (which may take the form of, but is not limited to, a magnetic storage medium; optical storage medium; magneto-optical storage medium; read only memory; random access memory; erasable programmable memory; flash memory; and so on), and one or more output components 107. The output components 107 may be configured to communicate with a display device 102, including providing one or more matrix codes for display on the display device. Additionally, although the display device 102 is illustrated as separate from the electronic device, it is understood that in various implementations the display device may be incorporated into the electronic device. The processing unit 105 of the electronic device 101 may execute instructions stored in the non-transitory storage medium 106 to derive information, dynamically generate one or more matrix codes (such as one or more QR codes) that include the derived information, and transmit the dynamically generated matrix code to the display device 102 utilizing the output component 107.

Subsequently, a reader device 103 may detect the matrix code displayed by the display device 102 and decode the information contained within the matrix code, such as information concerning the electronic device and/or sequencing information for the sequence of a plurality of matrix codes. The reader device may include one or more processing units 109 which execute instructions stored in one or more non-transitory storage media 111 in order to receive the plurality of matrix codes, decode the information within the plurality of matrix codes and combine the decoded information into a single piece of information. In addition, the reader device 103 may maintain sequence information for the plurality of matrix codes in order to combine the decoded information and/or maintain one or more of the matrix codes to compare to received codes for sequencing purposes. The reader device may also include an optical input device 110 (such as a camera, a barcode scanner, and so on) for detecting the matrix code displayed by the display device as well as a communication component 112 for communicating with one or more networks to provide the obtained matrix codes or decoded information to the one or more networks.

In various implementations, the electronic device 101 may transmit the one or more matrix codes by themselves to the display device 102 via the output component 107 for the display device to display only the one or more matrix codes at a particular time. However, in various other implementations (such as implementations where the electronic device is a television receiver, digital video recorder, or other such device that provides images to a display), the electronic device may transmit one or more images (such as a video stream) to the display device via the output component. In such implementations, the electronic device may combine the one or more matrix codes with the one or more images and transmit the combination to the display device via the output component.

In another implementation not shown, the reader device 103 may be located between the electronic device 101 and the display device 102 such that the reader device may receive the matrix codes prior to transmission to the display device. In this embodiment, the reader device 103 may utilize the communication component 112 to receive the sequence of matrix codes from the electronic device 101. In one particular implementation, the reader device 103 may be separate from the electronic device 101. In another implementation, the reader device 103 may be incorporated into the electronic device 101 or the display device 102.

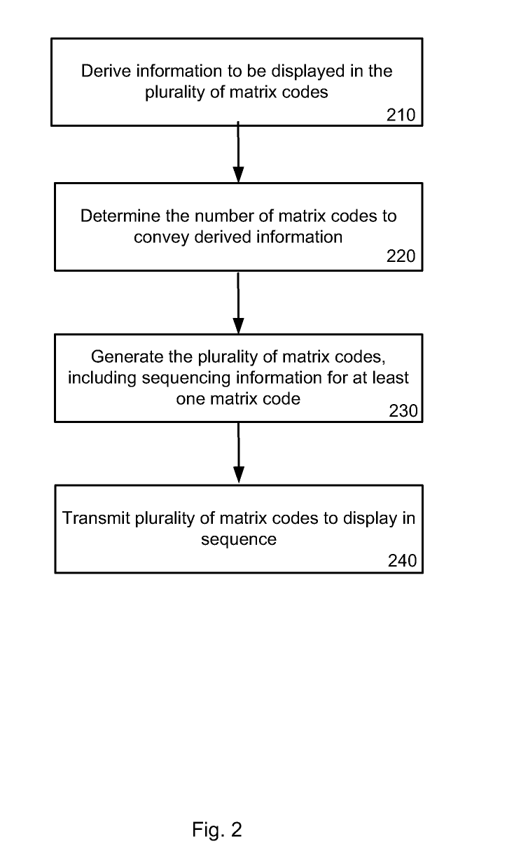

FIG. 2 is a flowchart depicting a method that may be executed by an electronic device to generate a plurality of sequenced matrix codes for display in sequence to provide encoded information beyond that of a single matrix code. The method may be performed by the electronic device 101 of FIG. 1 to provide a sequence of matrix codes to a display device to provide a sequence of segmented information through the plurality of matrix codes.

Beginning in operation 210, the electronic device may derive information to be provided through a plurality of sequenced matrix codes. In general, the information may be any data capable to being provided through one or more matrix codes, including information expressed in binary code, numeric values or alphanumeric characters. For example, the information may include data about the electronic device, a web address providing information related to a product or service, information to connect a reader device to a network or other electronic device, pixel information for an image, etc. Further, because the data may be provided in a sequence of a plurality of matrix codes, it need not be limited to the data capacity of a single matrix code, but instead may be distributed across any number of matrix codes to encompass a string of any length.

In addition, the electronic device may receive the information from a source, such as from a network device. Such information may be transmitted to the electronic device in any form for processing. Once received, the electronic device may transmit the information to a display device in a sequence of matrix codes, as described below. In one example, the information may be received as a matrix code embedded within a video that may be read and decoded by the electronic device. Such information may be the information derived in operation 210.

To derive the information to be provided in operation 210, the electronic device may transform the information into a form that may be encoded into the plurality of matrix codes. For example, the information may be transformed into a string of alphanumeric characters that may be encoded into a matrix code. In another example, the information may be transformed into a string of binary numbers, such as into binary information describing a pixel of an image. In yet another example, the information may be transformed into a string of numeric characters, such as a product identification code.

In operation 220, the electronic device may determine the number of matrix codes necessary to convey the derived information. For example, certain versions of a QR matrix code, if appropriately sized, can include approximately 4,000 alphanumeric characters. Thus, in operation 220, the electronic device may determine the character or byte size of the derived information and determine the number of matrix codes needed to transmit all of the derived information. For example, the derived information may be of sufficient size that three matrix codes are needed to convey the entirety of the information. In addition to determining the matrix codes in operation 220, the electronic device may also segment the information string into components such that one component or segment of information may be conveyed through a single matrix code. In other words, the electronic device may determine how the information string is divided between the plurality of sequence matrix codes in operation 220. In general, the information components may be contained within any number of sequenced matrix codes to accommodate the size of the information. However, in some embodiments, the number of the plurality of matrix codes may be constrained by the system capabilities of the electronic device or the reader device employed to generate and receive the sequence of codes.

In operation 230, the electronic device may generate a plurality of matrix codes, each of which includes one component of the segmented information derived in operation 210 above. To generate the plurality of codes, the electronic device may encode the information derived above into a matrix code form. Further, in one embodiment, the electronic device may encode one segment of the information into one of the plurality of matrix codes until each segment of the information is included in at least one matrix code.

Additional information may also be included in the plurality of matrix codes upon generation of the codes. For example, each matrix code may include orientation information in the code, such as position and alignment information to aid in reading of the code by a reader. As another example, the matrix codes may contain information identifying the electronic device creating and providing the matrix codes. In still another example, the matrix code may include information that limits the type of reader devices that may decode the displayed matrix codes, such that only those identified reader devices may decode the contained information. In general, each generated matrix code may include any information necessary or useful to aid in the receiving and decoding of the code may a reader device.

In addition to the information discussed above, the plurality of matrix codes may also include sequencing information concerning the plurality of sequenced matrix codes generated in operation 230. In one embodiment, each matrix code of the plurality of sequenced codes may include a number identifying the position of the code within the sequence of codes, as well as the total number of matrix codes in the sequence. For example, the matrix code may include sequence information in the form of “n of m”, where “n” is the particular number within the sequence associated with that particular matrix code and “m” is the total number of the plurality of matrix codes within the sequence. Thus, the matrix code may included the sequence information “4 of 10,” indicating that this particular matrix code is the fourth in a series of ten matrix codes. In another embodiment, each matrix code of the plurality of sequenced codes may include positional or sequential data, but only the first matrix code of the sequence may include the total number of matrix codes in a sequence. Thus, in this particular embodiment, a first matrix code may include the sequence information “1 of 10,” while each subsequent matrix code of the sequence merely includes an identification number, such as “2,” “3,” and so on. In addition to number sequences, other sequencing information may also be utilized to sequence the matrix codes, such as an alphanumeric sequence or any other type of a series of sequencing information.

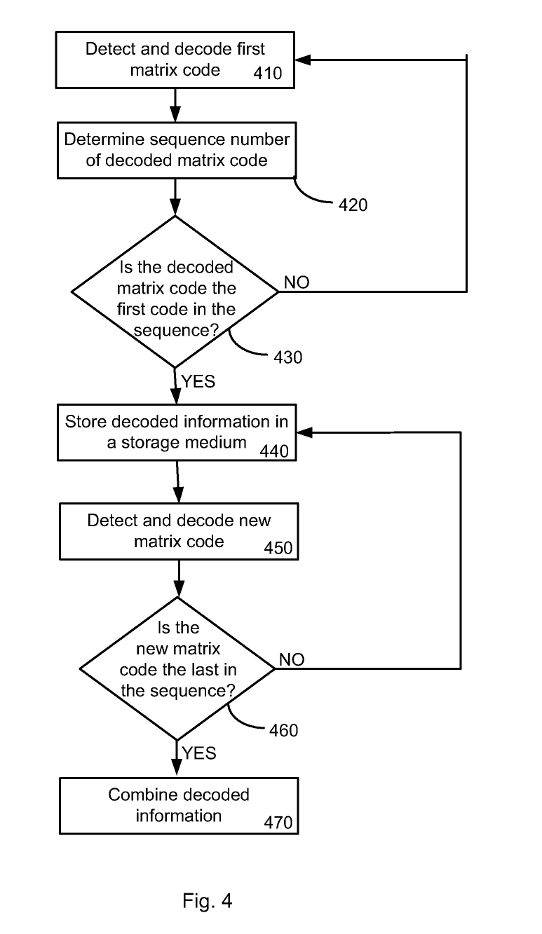

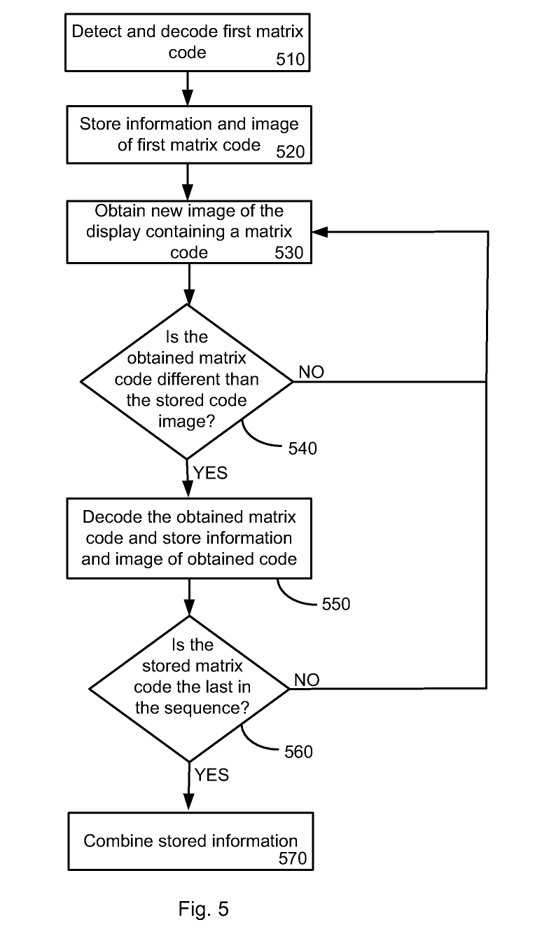

In still another embodiment, less than all of the sequenced matrix codes may contain identification and sequencing information. For example, in one embodiment, sequencing information as described above may be included in only the first matrix code of the plurality of sequenced codes. This information may then be utilized by a reader device to capture the correct number of subsequently displayed matrix codes to obtain the entire sequence of codes. As another example, identifying and sequencing information may be included periodically throughout the sequence of matrix codes, but not in every matrix code of the sequence. In general, identifying and sequencing information may be encoded within any number of the matrix codes within the sequence of codes to aid a reader device in properly receiving and processing the sequence of codes. The process of decoding the sequenced matrix codes and utilizing the sequencing information by a reader device is described in more detail below with reference to FIGS. 4 and 5.

Upon generation of the plurality of sequenced matrix codes in operation 230, the electronic device may transmit the plurality of codes to the display in operation 240. As described above, the sequence of matrix codes may be transmitted as, or embedded in, a video component of a multimedia presentation. In one embodiment, the sequence of matrix codes may be added or displayed over one or more images present on a video component. In another embodiment, the video component may be comprised solely of the plurality of sequenced matrix codes. Further, in operation 240, the electronic device may generally transmit the plurality of matrix codes in the sequence established in operation 220. In this manner, a display device may receive the plurality of matrix codes in sequence.

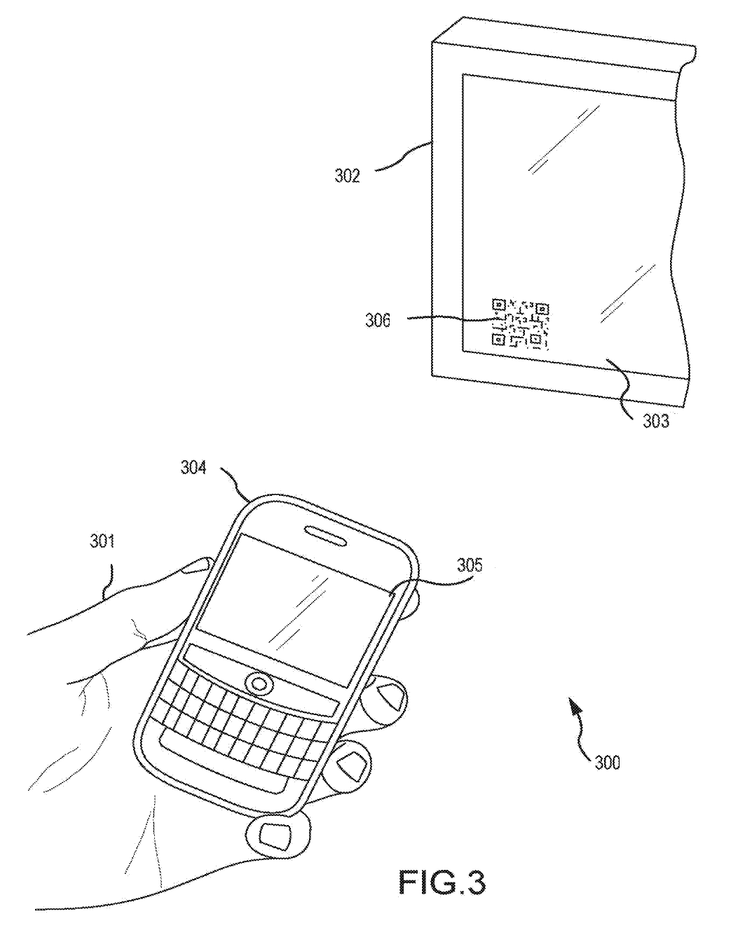

Once transmitted by the electronic device, the plurality of sequenced matrix codes may be displayed on a display device for reading by a reader device. FIG. 3 is an exemplary system for providing and receiving a plurality of sequenced matrix codes. As shown in FIG. 3, the system may include a television 302 (which may incorporate a television receiver for receiving television programming from a programming provider) and a reader device 304 operated by a user 301. Utilizing the operations described above, an electronic device (not shown) similar that the electronic device described above with relation to FIG. 1 may provide a plurality of sequenced matrix codes to the television 302 for display on the television screen 303. In response, the user 301 may utilize the reader device 304 to obtain the displayed matrix codes 306 and decode the matrix codes to collect the information transmitted through them.

To obtain the displayed sequenced matrix codes, the user 301 may utilize the reader device 304 to capture a video or a series of images of the display screen 303. The frames of the video or the images may be analyzed by the reader device 304 to decode and obtain the information stored in the sequence of matrix codes. Further, the obtained information may be transmitted by the reader device 304 to a recipient device, such as through a network connection. In one example, the captured video or series of images may be transmitted to the recipient device. In another example, the reader device 304 may derive the information contained within the codes and provide such information to the recipient device for processing.

It should also be appreciated that the sequence of plurality of matrix codes may generally be transmitted/displayed at any frame rate. For example, the sequence of matrix codes may be displayed at the same frame rate as the video component of a multimedia presentation, such that a different matrix code is displayed in each frame of the video. Alternatively, the sequence of matrix codes may be displayed at a slower frame rate. For example, each matrix code of the sequence of codes may be displayed for three seconds to provide ample time for the reader device 304 to retrieve each matrix code from the display device 302.

In addition, as stated above, the plurality of matrix codes may be displayed in sequence as determined by the electronic device. However, it should be appreciated that the plurality of matrix codes may be displayed in any sequence, with any number of matrix codes that are not a part of the sequence of codes displayed between. Further still, the plurality of matrix codes may be repeatedly displayed in sequence such that the reader device 304 may obtain the correct number of matrix codes if the reader device begins capturing the codes partway through the sequencing display. In such a configuration, the reader device may capture and discard the matrix codes until the first matrix code of the sequence is obtained or may capture and store the matrix codes until the entire sequence of codes are received.

As mentioned above, a reader device may be utilized to obtain the codes and decode the information stored therein as the sequence of matrix codes are displayed. FIG. 4 is a flowchart depicting a first method for an electronic device to receive and decode a plurality of sequenced matrix codes in sequence to receive information contained within the matrix codes. In general, the operations of FIG. 4 may be performed by a reader device, similar to that shown in FIGS. 1 and 3. Alternatively, while the operations described below discuss the reader device decoding the received matrix codes, one embodiment may include the reader device capturing the displayed matrix codes while the some or all of the decoding of the stored information may be performed by a recipient device that received the captured codes from the reader device. Further still, the operations of FIG. 4 may be performed for those embodiments described above that include sequencing information in all or some of the plurality of matrix codes.

Beginning in operation 410, the reader device may detect and decode a first matrix code from the display device. As described above, the reader device may obtain the matrix code from the display device by capturing a still image or video of the display screen. Further, the reader device may be configured to locate a matrix code embedded within an image or frame of a video component of a multimedia presentation. In this embodiment, the reader device may utilize image recognition technology to isolate the matrix code in an image and ignore the portions of the image not including the matrix code. For example, the reader device may utilize edge detection technology to analyze the captured image and detect the edges of the matrix code to isolate the code. In another example, the reader device may conduct a pattern recognition analysis on the captured image to detect the matrix code. Regardless, once the matrix code is detected, the reader device may decode the detected matrix code to obtain the information contained within the matrix code. In one embodiment, the reader device may utilize image recognition technology, as well as matrix code decoding techniques, to obtain the stored information.

As mentioned above, in some cases the first matrix code may include sequencing information for a sequence of plurality of matrix codes in the decoded information. This sequencing information may provide an indicator to the reader device that the information stored in the decoded matrix code is part of a sequence of information provided by a plurality of matrix codes. Thus, in operation 420, the reader device may the retrieve sequence information contained within the decoded matrix code. This sequence information may be obtained from the first matrix code and maintained by the reader device to aid the reader device in retrieving the entire sequence of matrix codes from the display.

In operation 430, the sequence information may then be analyzed by the reader device to determine if the detected and decoded matrix code is the first matrix code of the sequence. For example, the obtained sequence information may indicate that the decoded matrix code is one of a sequence of eight matrix codes. In another example, the sequence information may simply indicate that the decoded matrix code is the first of a sequence of codes of unknown number. If the reader device determines in operation 430 that the decoded matrix code contains sequencing information but is not the first matrix code of the sequence of codes, then the reader device may return to operation 410 and obtain another matrix code from the display device. Similarly, if the reader device determines in operation 430 that the decoded matrix code does not include any sequence information, the reader device may return to operation 410 and continue to detect and decode displayed matrix codes until sequence information is encountered.

If the reader device determines in operation 430 that the detected matrix code is the first code in a sequence of matrix codes, the reader device may decode and store or maintain the information obtained from the first matrix code in a storage medium in operation 440. Once the information from the first matrix code is stored, the reader device may then detect and decode another matrix code from the display in operation 450. In general, the detecting and decoding of the matrix code in operation 450 may be similar to the detecting and decoding performed by the reader device for the first matrix code. Also similarly, the reader device, upon decoding, may again obtain sequencing information contained within the new matrix code. Thus, in operation 460, the reader device may analyze the obtained sequence information to determine if the new matrix code is the last code provided in the sequence of plurality of matrix codes. For example, the next matrix code obtained in operation 450 may include an indication that the matrix code is the eighth code of a sequence of eight codes, indicating that the obtained matrix code is the last code of the current sequence. Alternatively, the new matrix code may include an indication identifying the new matrix code as the final code of the sequence without indicating the total number of codes in the sequence, through the use of a end-of-sequence flag or other indicator embedded within the code information.

As should be appreciated, the last code in the sequence may be relative to received matrix codes and not necessarily the last numbered code in the sequence. For example, in one embodiment, the sequence of matrix codes may be displayed in a random order and not necessarily sequentially. In this embodiment, the reader device may retain an indication of each matrix code of the sequence that has been received. For example, the reader device may store a number or other indicator representative of the matrix codes of the sequence of codes that have been received. In this embodiment, the “last” matrix code of operation 460 may be the final matrix code received that completes the sequence of matrix codes, even though that matrix code may not be the last numbered matrix code. For example, the reader device may have received every matrix code of a sequence of eight matrix codes, absent the fourth matrix code of the sequence. Thus, in this example, the “last” matrix code determined in operation 460 may be the fourth matrix code of the sequence. Therefore, in those embodiments where the sequence of matrix codes are received in a random order, the “last” matrix code may be the matrix code of the sequence that completes the sequence.

If the reader device determines in operation 460 that the obtained matrix code is not the last code in the sequence, the reader device may then return to operation 440 to store the information obtained from the obtained matrix code and detect and decode a new matrix code displayed in operation 450. This loop may continue until the final matrix code of the sequence of plurality of matrix codes is detected and decoded by the reader device. Thus, when the reader device determines the final matrix code of the sequence has been detected and decoded in operation 460, the reader device may combine the stored information for each of the decoded matrix codes of the sequence of plurality of matrix codes into a single piece of information in operation 470. In this manner, the reader device may perform the operations of the method of FIG. 4 to receive information that is segmented into and displayed through a plurality of sequenced matrix codes in a video component displayed on the display device.

An alternative embodiment of the method of FIG. 4 may include capturing and storing any matrix code with sequencing information until each matrix code of the sequence of matrix codes is obtained. Thus, in this embodiment, the reader device may obtain any matrix code of the sequence of matrix codes and store the matrix code and/or decoded information. The reader device may then continue to obtain and decode matrix codes until each matrix code of the sequence of matrix codes is obtained, at which point the reader device may combine the decoded information in operation 470.

As mentioned above, the operations of FIG. 4 may be performed for those embodiments that include sequencing information in all or some of the plurality of matrix codes. In one embodiment described above, however, only the first and last matrix codes of the sequence may contain information concerning the sequencing of the plurality of matrix codes. For those embodiments, FIG. 5 depicts a second method for an electronic device to receive and decode a plurality of sequenced matrix codes in sequence to receive information contained within the matrix codes. Similar to FIG. 4, the operations of FIG. 5 may be performed by a reader device as described above.

Beginning in operation 510, the reader device may detect and decode a first matrix code displayed on a display device. In general, the reader device may perform these operations in a similar manner as those described above, such as by capturing a series of images or a video of the display and decoding the displayed matrix code. In operation 520, the reader device may store the information decoded from the first matrix code in one or more storage mediums. In addition to storing the information decoded from the first matrix code, the reader device may also store an image of the first matrix code in the storage medium. The image of the first matrix code may be stored on a display in communication with the reader device or in another storage medium. Further, the image of the first matrix code may be stored in any configuration, such as pixel data or binary code.

In operation 530, the reader device may capture another image or video frame of the display. In some instances, such as when each matrix code of the sequence is displayed for several seconds or over several frames of the video component, the video component of the new image may have changed but the matrix code may be the same as the matrix code captured in operation 510. In other words, the matrix code displayed and detected in operation 530 may be the same matrix code displayed and obtained in operation 510, even though the rest of the image may have changed. In other instances, however, the matrix code displayed on the display device may have changed from the first image such that the reader device may obtain a new matrix code from the display device in operation 530.

In operation 540, the reader device may compare the matrix code obtained in operation 530 to the maintained image of the first matrix code to determine if a new matrix code has been displayed on the display device and detected by the reader device. As mentioned above, in those instances where each matrix code of the sequence of codes is displayed for several seconds, the matrix code obtained in operation 530 by the reader device may be the same as the matrix code obtained in operation 510. In these cases, the reader device may return to operation 530 to obtain a new image of the display device containing a matrix code to compare to the stored image. If the new matrix code is different than the stored image, however, than the reader device may determine that the next matrix code in the sequence of plurality of matrix codes has been obtained. In this manner, the reader device may repeatedly take images of the display device to detect when a new matrix code in the sequence of the plurality of matrix codes is displayed on the display device.

In one embodiment not shown, the reader device may obtain and decode the matrix code of the new image in operation 530. Thus, in operation 540, the reader device may compare the decoded information from the first matrix code the newly obtained matrix code to determine if a new matrix code has been displayed rather than comparing the images of the first and new matrix code. In general, the reader device may compare the first received matrix code and the new matrix code in any manner to determine when a new matrix code is displayed on the display device.

When a new matrix code is obtained from the display device as determined in operation 540, the reader device may decode the new matrix code and store the decoded information into the storage medium in operation 550. In addition, the reader device may also maintain the image of the newly obtained matrix code for comparison to any subsequent matrix code images obtained, similar to operation 520 above. Further, once the information in the obtained matrix code is decoded, the reader device may analyze the decoded information for sequencing information and determine if the obtained matrix code is the last code in the sequence of the plurality of matrix codes in operation 560. In general, this information may be contained within the matrix code, similar to sequencing information described above. In addition, the last code in the sequence may be relative to received matrix codes and not necessarily the last numbered code in the sequence, as described above. Rather, the “last” matrix code may be the matrix code of the sequence that completes the sequence for those embodiments where the sequence of matrix codes is received in a random or non-sequential manner.

If the reader device determines that the obtained matrix code is not the last code in the sequence in operation 560, the reader device may return to operation 530 and obtain another image of the display device to detect when the next matrix code in the sequence is displayed. However, if the reader device determines that the matrix code is the last code in the sequence, then the reader device may combine the stored information for each of the decoded matrix codes of the sequence of plurality of matrix codes into a single piece of information in operation 570. In this manner, the reader device may perform the operations of the method of FIG. 5 to receive information that is segmented into and displayed through a plurality of sequenced matrix codes.

In the present disclosure, the methods disclosed may be implemented as sets of instructions or software readable by a device. Further, it is understood that the specific order or hierarchy of steps in the methods disclosed are examples of sample approaches. In other embodiments, the specific order or hierarchy of steps in the method can be rearranged while remaining within the disclosed subject matter. The accompanying method claims present elements of the various steps in a sample order, and are not necessarily meant to be limited to the specific order or hierarchy presented.

The described disclosure may be provided as a computer program product, or software, that may include a non-transitory machine-readable medium having stored thereon instructions, which may be used to program a computer system (or other electronic devices) to perform a process according to the present disclosure. A non-transitory machine-readable medium includes any mechanism for storing information in a form (e.g., software, processing application) readable by a machine (e.g., a computer). The non-transitory machine-readable medium may take the form of, but is not limited to: a magnetic storage medium (e.g., floppy diskette, video cassette, and so on); optical storage medium (e.g., CD-ROM); magneto-optical storage medium; read only memory (ROM); random access memory (RAM); erasable programmable memory (e.g., EPROM and EEPROM); flash memory; and so on.

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes.

While the present disclosure has been described with reference to various embodiments, it will be understood that these embodiments are illustrative and that the scope of the disclosure is not limited to them. Many variations, modifications, additions, and improvements are possible. More generally, embodiments in accordance with the present disclosure have been described in the context or particular embodiments. Functionality may be separated or combined differently in various embodiments of the disclosure or described with different terminology. These and other variations, modifications, additions, and improvements may fall within the scope of the disclosure as defined in the claims that follow.

What is claimed is:

1. A method for transmitting information in a plurality of matrix codes, the method comprising:
deriving, utilizing an electronic device, information to be transmitted in the plurality of matrix codes;
segmenting, utilizing an electronic device, the information into a plurality of segments corresponding to the plurality of matrix codes;
generating, utilizing an electronic device, the plurality of matrix codes wherein the plurality of matrix codes include the segmented information and at least one of the plurality of matrix codes includes sequence information corresponding to the plurality of matrix codes; and
transmitting, utilizing the electronic device, the plurality of matrix codes to at least one display device in a video component of a multimedia presentation,
wherein the plurality of matrix codes is decodable by at least one reader device that optically detects the plurality of matrix codes displayed on the at least one display device.

2. The method of claim 1 wherein the sequence information includes an indication of the position of the at least one of the plurality of matrix codes within the sequence of the plurality of matrix codes and an indication of the total number of matrix codes in the plurality of matrix codes.

3. The method of claim 2 wherein the sequence information is included in each of the plurality of matrix codes.

4. The method of claim 2 wherein the sequence information is included in the first of the plurality of matrix codes.

5. The method of claim 1 wherein the plurality of matrix codes comprise a plurality of QR codes.

6. The method of claim 1 wherein the operation of transmitting comprises:
combining the plurality of matrix codes with a plurality of video frames of a multimedia presentation, wherein each matrix code of the plurality of matrix codes is combined with at least one video frame; and
transmitting the combined matrix codes and video frames to that at least one display device.

7. The method of claim 6 wherein the each matrix code of the plurality of matrix codes is combined with one video frame such that the plurality of matrix codes are transmitted to the at least one display device at the same frame rate as the video of the multimedia presentation.

8. The method of claim 6 wherein the each matrix code of the plurality of matrix codes is combined with a plurality of concurrent video frames such that, upon display on the at least one display device, each matrix code is displayed for several seconds.

9. A method for receiving information encoded in a sequence of a plurality of matrix codes, the method comprising:
receiving a first matrix code of the sequence of the plurality of matrix codes, the first matrix code including a first segment of information and a first set of sequence information corresponding to the plurality of matrix codes;
decoding the first matrix code to obtain the first segment of information and the first set of sequence information;
receiving at least a subsequent matrix code of the sequence of the plurality of matrix codes, the subsequent matrix code including a second segment of information;
decoding the subsequent matrix code to obtain the second segment of information;
determining if the subsequent matrix code is the last matrix code in the sequence of the plurality of matrix codes; and
combining the first segment of information and the second segment of information if the second matrix code is the last matrix code in the sequence of the plurality of matrix codes.

10. The method of claim 9 further comprising:
storing the first segment in a storage medium prior to receiving the subsequent matrix code of the sequence of the plurality of matrix codes.

11. The method of claim 9 wherein the first set of sequence information includes at least an indication of the position of the first matrix code of the sequence of the plurality of matrix codes and an indication of the total number of matrix codes in the plurality of matrix codes.

12. The method of claim 9 wherein the subsequent matrix code further includes a second set of sequence information, the second set of sequence information including at least an indication of the position of the subsequent matrix code of the sequence of the plurality of matrix codes.

13. The method of claim 9 wherein the receiving operations comprises:
utilizing an optical component of a reader device to obtain a video image of a display device, wherein the display device displays at least the first matrix code of the sequence of the plurality of matrix codes and the subsequent code of the sequence of the plurality of matrix codes.

14. The method of claim 9 further comprising:
repeating the operations of receiving matrix codes and decoding matrix codes until the last matrix code in the sequence of the plurality of matrix codes is received.

15. A reader device comprising:
at least one processing unit; and
a storage medium, the storage medium storing a computer-executable code that, when executed by the at least one processing unit, causes the reader device to perform the operations of:
receiving a first video image of a display device, the first video image including a first matrix code of a sequence of a plurality of matrix codes, the first matrix code including an encoded first segment of information and a first set of sequence information corresponding to the plurality of matrix codes;
decoding the first matrix code to obtain the first segment of information and the first set of sequence information;
maintaining an image of the first matrix code;
obtaining a second video image of a display device, the second video image including a matrix code;
comparing the first video image and the second video image to determine the presence of a new matrix code in the second video image;
decoding the new matrix code to obtain a second segment of information if a new matrix code is included in the second video image; and
combining the first segment of information and the second segment of information.

16. The reader device of claim 15 further comprising:
a communication component to communicate the combine first segment of information and the second segment of information to a network.

17. The reader device of claim 15 wherein the next matrix code includes a second set of sequence information corresponding to the plurality of matrix codes and the computer-executable code further causes the reader device to perform the operations:
analyzing the second set of sequence information to determine if the next matrix code is the last matrix code in the sequence of the plurality of matrix codes.

18. The reader device of claim 15 wherein the first set of sequence information includes at least an indication of the position of the first matrix code of the sequence of the plurality of matrix codes and an indication of the total number of matrix codes in the plurality of matrix codes.

19. The reader device of claim 15 further comprising:
a optical reader to receive the first video image and obtain the second video image.

20. The reader device of claim 19 wherein the receiving operation comprises:
obtaining a video image of a display device, wherein the display device displays at least the first matrix code of the sequence of the plurality of matrix codes.
